(19) United States
(12) Patent Application Publication
(10) Pub. No.: US 2005/0056969 A1
(43) Pub. Date: Mar. 17, 2005

(54) Forming homogeneous mixtures of organic materials for physical vapor deposition using a solvent

(75) Inventors: Syamal K. Ghosh, Rochester, NY (US); Donn B. Carlton, Hamlin, NY (US); Tukaram K. Hatwar, Penfield, NY (US)

Correspondence Address: Thomas H. Close;Patent Legal Staff, Eastman Kodak Company, 343 State Street, Rochester, NY, 14650-2201, US

(73) Assignee: Eastman Kodak Company

(21) Appl. No.: 10/663,635

(22) Filed: Sep. 16, 2003

(51) Int. Cl. B06B 1/02; B29B 7/02; B29B 7/08; B29B 7/84; B29B 9/00

(52) U.S. Cl. 264/442; 264/349; 264/102; 264/122; 264/85

(57) ABSTRACT

A method for forming homogeneous mixtures of powders of organic materials, which include, at least one dopant component and one host component, to provide a homogeneous mixture for use in thermal physical vapor deposition to produce an organic layer on a substrate for use in an organic light-emitting device. The method includes combining organic materials, such organic materials including at least one dopant component and one host component and providing a solvent with the organic materials to form a suspension of organic powders in the solvent. Subsequently mixing the suspension to form a solution of the organic materials in the solvent and finally evaporating the solvent from the solution leaving a homogeneous mixture of organic powder.

### CROSS REFERENCE TO RELATED APPLICATIONS

Reference is made to commonly assigned U.S. patent application Ser. No 09/898,369 filed Jul. 3, 2001 entitled “Method of Handling Organic Material in Making An Organic Light-Emitting Device” by Van Slyke et al.; U.S. patent application Ser. No. 10/073,690 filed Feb. 11, 2002, entitled “Using Organic Materials in Making An Organic Light-Emitting Device” by Ghosh et al., U.S. patent application Ser. No. 10/195,947 filed Jul. 16, 2002, entitled “Compacting Moisture-Sensitive Organic Material in Making An Organic Light-Emitting Device” by Ghosh et al., U.S. patent application Ser. No. 10/226,600 filed Aug. 23, 2002, entitled “Solid Compacted Pellet of Organic Material for Vacuum Deposition of OLED displays and Method of Making Same” by Ghosh et al., and U.S. patent application Ser. No. 10/348,118 filed Jan. 17, 2003, entitled “Using Compacted Organic Materials In Making White Light-emitting OLEDS” by Ghosh et al., U.S. patent application Ser. No. ______ filed concurrently herewith, entitled “Forming Homogeneous Mixtures of Organic Materials For Physical Vapor Deposition Using Melting” by Ghosh et al, U.S. patent application Ser. No. ______ filed concurrently herewith, entitled “Forming Homogeneous Mixtures of Organic Materials For Physical Vapor Deposition Using Dry Mixing” by Ghosh et al, and U.S. patent application Ser. No. ______ filed concurrently herewith, entitled “Forming Homogeneous Mixtures of Organic Materials For Physical Vapor Deposition Using Wet Mixing” by Ghosh et al, the teachings of which are incorporated herein.

### FIELD OF THE INVENTION

The present invention relates to forming homogeneous mixtures of two or more organic powder components for use in making an organic layer by physical vapor deposition on a substrate, which will form a part of an OLED display.

### BACKGROUND OF THE INVENTION

An organic light-emitting diode (OLED), also referred to as an organic electroluminescent device, can be constructed by sandwiching two or more organic layers between first and second electrodes.

Organic materials, thickness of vapor-deposited organic layers, and layer configurations, useful in constructing an organic light-emitting device are described for example, in commonly assigned U.S. Pat. Nos. 4,356,429; 4,539,507; 4,720,432; and 4,769,292, the disclosures of which are herein incorporated by reference.

Organic materials useful in making OLED displays, for example organic hole-transporting materials, organic light-emitting materials with an organic dopant, and organic electron-transporting materials can have relatively complex molecular structures with relatively weak molecular bonding forces, so care must be taken to avoid decomposition of the organic material during physical vapor deposition.

The aforementioned organic materials are synthesized to a relatively high degree of purity, and are provided in the form of powders, flakes, or granules. Such powders or flakes have been used heretofore for placement into a physical vapor deposition source wherein heat is applied for forming a vapor by sublimation or vaporization of the organic powder, the vapor condensing on a substrate to provide an organic layer thereon. In order to form a layer having more than one organic component, such as a host and a dopant component, it is desirable to co-evaporate simultaneously from two adjacent sources so that the organic components are mixed in the vapor-state prior to forming a layer on a substrate.

The co-evaporation process has several disadvantages which include (a) the vapor deposition chamber must be large to accommodate the evaporation sources for both the dopant and host component organic materials; (b) the large chambers necessary to complete co-evaporation are costly; (c) the larger the chamber, the more time that is required to reduce the pressure of the chamber prior to vaporization; and (d) each evaporation source containing a host or dopant component material must be vaporized by an independent power source, thereby increasing the cost of the co-evaporation process.

The rate of vaporization of each individual deposition source is crucial because that determines the chemical composition of the deposited organic layer on the substrate. In other words, the deposition rate determines the amount of vapor deposited on a substrate for a given length of time. Since the weight percentage of the dopant component in organic layers is lower than that of the host component, it is imperative that the deposition rate for the dopant component be adjusted accordingly. If the rate of vaporization of individual sources is not precisely controlled, the chemical composition of the vapor deposited on the substrate will be different from what is required to form a highly efficient OLED display.

Several problems associated with co-evaporation of organic powders, flakes or granules have also been discovered. Such problems include:
(i) powders, flakes, or granules are difficult to handle because they can acquire electrostatic charges via a process referred to as triboelectric charging;
(ii) powders, flakes, or granules of organic materials generally have a relatively low physical density (expressed in terms of weight per unit volume) in an approximate range from 0.05 to 0.2 g/cm³, compared to a physical density of an idealized solid organic material of approximately 1 g/cm³;
(iii) powders, flakes, or granules of organic materials have an undesirably low thermal conductivity, particularly when placed in a physical vapor deposition source which is disposed in a chamber evacuated to pressures as low as 10⁻⁶ Torr. Consequently, powder particles, flakes, or granules are heated only by radiative heating from a heated source, and by conductive heating of particles or flakes directly in contact with heated surfaces of the source. Powder particles, flakes, or granules which are not in contact with heated surfaces of the source are not effectively heated by conductive heating due to a relatively low particle-to-particle contact area; and
(iv) powders, flakes, or granules typically have a high ratio of surface area/volume and a correspondingly high propensity to entrap air and moisture between particles under ambient conditions. Consequently, a charge of organic powders, flakes, or granules loaded into a physical vapor deposition source, which is disposed in a chamber must be thoroughly outgased by preheating the source once the chamber has been evacuated to a reduced pressure.

If outgasing is omitted or is incomplete, particulate can be ejected from the evaporation source during the physical vapor deposition process. An OLED, having multiple organic layers, can become functionally inoperative if such layers include particles or particulates. Compaction of organic powders for making OLED displays using a physical vapor deposition method is described by Van Slyke et al. in a commonly assigned U.S. patent application Publication No. 2003/0008071 A1, the disclosure of which is incorporated herein by reference.

Organic powders, flakes, or granules can lead to nonuniform heating of such organic materials in physical vapor deposition sources with attendant spatially nonuniform vaporization of organic material, which can, result in potentially nonuniform vapor-deposited organic layers formed on a structure.

### SUMMARY OF THE INVENTION

It is an object of the present invention to provide efficient methods of mixing organic materials adaptable for making on organic layer on a structure, which will form a part of an OLED display.

It is another object of the present invention to provide a homogeneous mixture of organic materials including at least one host component and at least one dopant component adaptable for making an organic layer on a structure, which will form a part of an OLED display.

These objects are achieved in present invention by providing A method for forming homogeneous mixtures of powders of organic materials including at least one dopant component and one host component to provide a homogeneous mixture for use in thermal physical vapor deposition to produce an organic layer on a substrate for use in an organic light-emitting device, comprising:
a) combining organic materials, such materials including at least one dopant component and one host component;
b) providing a solvent with the organic materials to form a suspension of organic materials in the solvent;
c) mixing the suspension at a temperature sufficient to form a solution of the organic materials in the solvent; and
d) evaporating the solvent from the solution leaving a homogeneous mixture of organic powder.

It has been discovered that by providing a solvent as described in the above method, more effective homogeneous mixtures of organic materials effectively can be made.

A feature of the present invention is that solvent mixing requires inexpensive equipment and materials to produce a homogeneous mixture of organic materials.

Another feature of the present invention is that the solvent mixing process does not chemically alter the integrity of the organic molecules and the mixing can be accomplished in a relatively short time.

Another feature of the present invention is an effective way to provide homogeneous mixtures of organic materials that can be vaporized from a single source thereby avoiding the problems associated with co-evaporation of single component materials.

Another feature of the present invention is that compacted pellets can be formed from homogenous mixtures of organic materials thereby avoiding the problems associated with vaporization of organic powders, flakes or granules.

Another feature of the present invention is that a compacted pellet formed from a homogeneous mixture of organic materials can be evaporated for a longer duration from a single evaporation source rather than co-evaporation from a multiple evaporation sources as in single component materials.

### BRIEF DESCRIPTION OF THE DRAWINGS

FIG. 1 depicts a schematic flow chart of mixing organic materials using organic solvents.

The term “powder” is used herein to denote a quantity of individual particles, which can be flakes, granules, or mixtures of varied particles and shapes comprising single or plurality of molecular species.

### DETAILED DESCRIPTION OF THE INVENTION

The organic layers of an OLED display include an organic or organo-metallic material that produces light, known as electroluminescence (EL), as a result of electron-hole recombination in the layer. Hereinafter, the term “organic” will be taken to include both purely organic as well as organo-metallic materials.

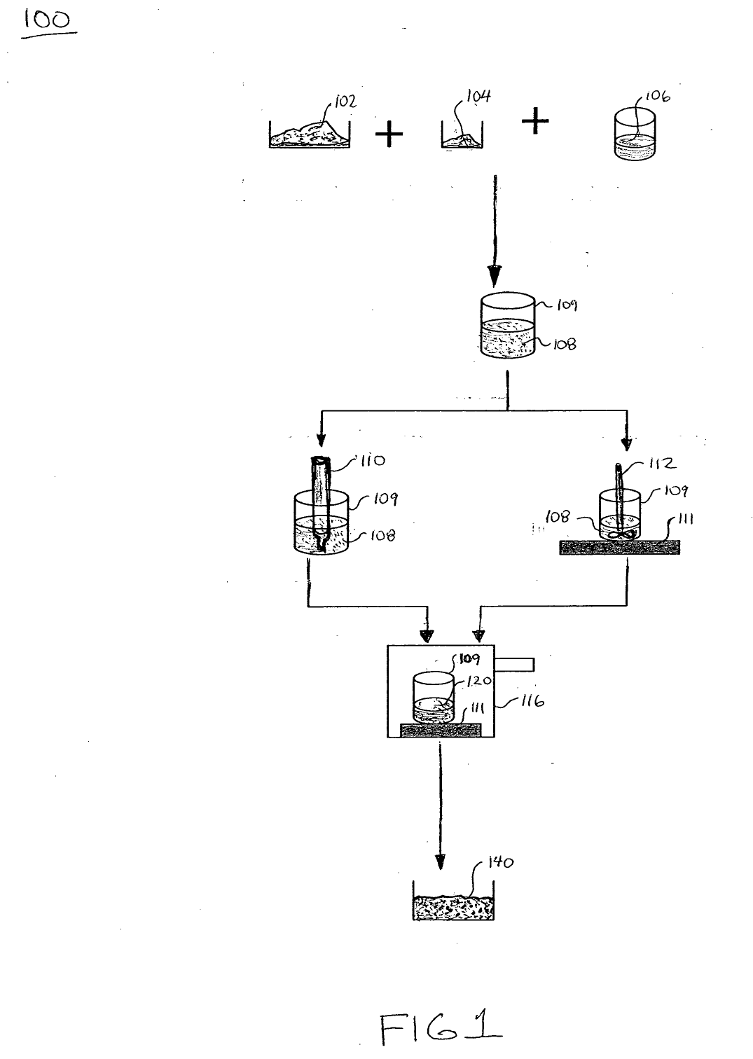

Turning to FIG. 1, a schematic flow chart of a solution mixing process 100 of organic materials in powder form is shown. The process begins by combining the organic materials, which include at least one host component 102 and at least one dopant component 104. Depending on the application and functionality of the organic mixture, the dopant component 104 varies from 0.1 to 20% by weight of the total mixture weight. The organic materials used as a host component 102 in the present invention can be Alq3, NPB and TBADN. The organic materials used as a dopant component 104 can be DCJTP, Rubrene, OP31, DPQA and DBzR. The next step of the process includes providing a solvent 106 with the host component 102 and dopant component 104 in a container 109, to form a suspension 108. The solvent can be tetrahydrofuran (THF). Another solvent, dichloromethane can be added to the THF to promote dissolution of the host component 102 and dopant component 104.

The next process step includes mixing the suspension 108 until the host component 102 and dopant component 104 form a solution of organic materials in a solvent 120. In one embodiment, the suspension 108 is mixed by an ultrasonic horn 110 to promote dissolution of the host component 102 and dopant component 104, thereby forming the solution of organic materials in the solvent 120. The ultrasonic frequency is between 10 and 30 kHz. A continuous mode ultrasonic energy is applied for a duration of 60 to 180 seconds. If the solution of organic materials in the solvent 120 is not obtained within the duration, another pulse of continuous mode ultrasonic energy is applied for 60 to 180 seconds. This process is repeated until the solution of organic materials in the solvent 120 is obtained.

Another embodiment of the present invention includes simultaneous heating and mixing of the suspension 108 to obtain the solution of organic materials in the solvent 120. The suspension 108 is heated to a temperature in a range between 50 and 100° C., the temperature sufficient to form the solution of organic materials in the solvent 120 by a heater 111. The mixing apparatus can be a magnetic stirrer, an ultrasonic horn or a turbine stirrer 112. The suspension 108 is heated and mixed until the solution of organic materials in the solvent 120 is obtained.

The process then includes evaporating the solvent 106 from the solution of organic materials in the solvent 120 leaving a homogeneous mixture of organic powder 140. Evaporation of the solvent 106 can be obtained by providing a controlled atmosphere such as a reduced pressure chamber 116 operating in a range of pressures between 10⁻¹ to 10⁻³ Torr. Alternatively, the solution 120 can also be heated in a controlled atmosphere of inert gas such as nitrogen gas, argon gas or a mixture thereof. As the solvent 106 is evaporated, by heat, under reduced pressure, or in the presence of an inert gas, the solution of organic materials in the solvent 120 can be mixed to assure that the mixture of organic materials remains chemically homogeneous.

When the solvent 106 is completely evaporated, a homogeneous mixture of organic powders 140 is obtained. The homogenous mixture of organic powders 140 is suitable for thermal physical vapor deposition to produce an organic layer on a substrate for use in an OLED display. Furthermore, the homogeneous mixture of organic powders 140 can be compacted at pressures in a range of 3,000 to 20,000 pounds per square inch to form pellets suitable for physical vapor deposition to produce an organic layer on a substrate for use in an OLED display.

### WORKING EXAMPLES

### Example 1

### The Blue Emission Layer

First, 2.0 grams of dopant component organic material TBP and 8.0 grams of host component organic material TBADN were combined in a glass beaker. Next, 50 to 80 cc of an organic solvent, tetrahydrofuran (THF), were added to the organic materials to form a suspension. The suspension was mixed and heated to 80° C. until a solution was obtained. The heating at 80° C. was continued in order to evaporate the solvent while the solution was mixed.

The mixing and heating continued until the solvent was completely evaporated, leaving behind a homogeneous mixture of organic powder, which was compacted at a pressure of 5,000 pounds per square inch to form pellets for use in physical vapor deposition. The compacted pellet was placed in a quartz boat and the pellet was heated from the top using a Ta heater according to the prior art described by S. Van Slyke et al, SID 2002 Digest, pp. 886-889, 2002, which is incorporated herein for reference. Several OLED displays having the following structure were formed on a glass substrate coated with an indium-tin oxide anode:
Hole injection layer: CFx. Thickness=5 nm
HTL: NPB. Thickness=75 nm
EML: TBADN+2% TBP. Thickness=20 nm
ETL: Alq3. Thickness=35 nm
Cathode: MgAg. Thickness=200 nm

Initially, five OLED displays were made wherein the EML was formed by using a compacted pellet weighing approximately 2.0 grams and other organic layers such as a HTL and an ETL were formed using organic materials and a top heated quartz boat. Another set of five OLED displays was made after one hour of continuous evaporation. The compacted pellet was heated continuously for approximately 200 minutes until the pellet was completely consumed and a set of five OLED displays were made at intervals of 30 minutes. A shutter during the continuous deposition process protected the substrates and the shutter was opened only when emission layers were deposited to form an OLED display.

The average EL results of each set of five OLED displays are shown in Table 1. The OLED displays in group A denote the average performance of five OLED displays made at the beginning of the deposition process, OLED displays in group B denote the average performance of five displays made after 120 minutes of continuous deposition and OLED displays in group C denote the average EL performance of five OLED displays made after 180 minutes of deposition.

TABLE 1
EL results of blue OLED displays formed according to the invention.

| Experi- | EML | OLED | Drive | Luminance | |
|---|---|---|---|---|---|
| ment | Composition | displays | Voltage | Yield (cd/A) | CIEx, y |
| 1 | TBADN + 2% | A | 7.1 V | 2.51 | 0.15, 0.20 |
| | TBP | | | | |
| 2 | TBADN + 2% | B | 7.0 V | 2.35 | 0.14, 0.19 |
| | TBP | | | | |
| 3 | TBADN + 2% | C | 6.8 | 2.40 | 0.14, 0.18 |
| | TBP | | | | |

The experimental results summarized in Table 1 indicate that the EL characteristics such as drive voltage, luminance yield and color coordinates, CIEx,y of the blue emission layer formed according to the invention remained uniform throughout the entire length of the deposition process indicating that the composition of the organic materials which included 98% TBADN (host) and 2% TBP (dopant) remained unchanged.

### Example 2

### The Red Emission Layer

First, 0.5 grams of organic dopant material Rubrene, 0.15 grams of organic dopant material DCJTB, 4.675 grams of organic host material TBADN, and 4.675 grams of organic host material Alq3 were placed in a glass beaker. Next, 50 to 80 cc of organic solvent tetrahydrofuran (THF) were added to the organic materials to form a suspension. The beaker containing the suspension was heated to 80° C. and mixed until a solution was obtained. To aid complete dissolution of the organic materials, 10 cc of the solvent, dichloromethane was added.

The mixing and heating was continued until the solvent was completely evaporated, leaving behind a homogeneous mixture of organic powder, which was compacted at a pressure of 5,000 pounds per square inch to form a pellet for physical vapor deposition. The compacted pellet was placed in a quartz boat and the pellet was heated from the top using a Ta heater according to the prior art described by S. VanSlyke et al, SID 2002 Digest, pp.886-889, 2002, which is incorporated herein for reference. Several OLED displays having the following structure were formed on a glass substrate coated with an indium-tin oxide anode:
Hole injection layer: CFx. Thickness=5 nm
HTL: NPB. Thickness=75 nm
EML: Host−[TBADN+Alq3(1:1)]/Dopant−5% Rubrene+1.5% DCJTB. Thickness=35 nm
ETL: Alq3. Thickness=35 nm
Cathode: MgAg. Thickness=200 nm.

Initially, five OLED displays were made wherein the EML was formed by using a compacted pellet weighing approximately 2 grams, and other organic layers such as a HTL and an ETL were formed using organic powder and top heated quartz boat. Another set of five OLED displays was made after 30 minutes of continuous evaporation. The compacted pellet was heated continuously for approximately 100 minutes until the pellet was completely consumed and a set of five OLED displays were made at the interval of every 30 minutes. A shutter protected the substrates during the continuous deposition process and that shutter was opened only when emission layers were deposited to form an OLED display.

The average EL results of each set of five OLED display are shown in Table 2. The OLED displays in group D denote the average performance of five OLED displays made at the beginning of the deposition process, OLED displays in group E denote the average performance of five displays made after 30 minutes of continuous deposition and OLED displays in group F denote the average performance of five OLED displays made after 90 minutes of deposition.

TABLE 2
EL results of red OLED displays formed according to the invention.

| Experi- | EML | OLED | Drive | Luminance | |
|---|---|---|---|---|---|
| ment | Composition | displays | Voltage | Yield (cd/A) | CIEx, y |
| 4 | TBADN + Alq3 | D | 9.2 | 4.8 | 0.59, 0.40 |
| | (1:1) 5% | | | | |
| | Rubrene + 1.5% | | | | |
| | DCJTB | | | | |
| 5 | TBADN + Alq3 | E | 9.0 | 4.42 | 0.60, 0.40 |
| | (1:1) 5% | | | | |
| | Rubrene + 1.5% | | | | |
| | DCJTB | | | | |
| 6 | TBADN + Alq3 | F | 9.0 | 4.43 | 0.60, 0.40 |
| | (1:1) 5% | | | | |
| | Rubrene + 1.5% | | | | |
| | DCJTB | | | | |

The experimental results summarized in Table 2 indicate that the EL characteristics of the red emission layer formed according to the invention remained uniform throughout the entire length of the deposition process. The results indicate that the composition of the organic materials, which included a 1:1 ratio of TBADN: Alq3 as the host component, which was doped with 5% Rubrene and 1.5% DCJTB remained unchanged throughout the deposition process.

The invention has been described in detail with particular reference to certain preferred embodiments thereof, but it will be understood that variations and modifications can be effected within the spirit and scope of the invention.

### PARTS LIST

100 solution mixing process
102 host component
104 dopant component
106 solvent
108 suspension
109 container
110 ultrasonic horn
111 heater
112 turbine stirrer
116 reduced pressure chamber
120 solution of organic materials in the solvent
140 homogeneous mixture of organic powders.

1. A method for forming homogeneous mixtures of powders of organic materials including at least one dopant component and one host component to provide a homogeneous mixture for use in thermal physical vapor deposition to produce an organic layer on a substrate for use in an organic light-emitting device, comprising:
a) combining organic materials, such materials including at least one dopant component and one host component;
b) providing a solvent with the organic materials to form a suspension of organic materials in the solvent;
c) mixing the suspension at a temperature sufficient to form a solution of the organic materials in the solvent; and
d) evaporating the solvent from the solution leaving a homogeneous mixture of organic powder.

2. The method of claim 1 further including:
(e) compacting the homogenous mixture of organic powders, to form a pellet suitable for thermal physical vapor deposition to produce an organic layer on a substrate for use in an organic light-emitting device.

3. The method of claim 1 wherein the dopant component varies between 0.1 and 20% by weight of the total mixture weight.

4. The method of claim 1 wherein the solvent is tetrahydrofuran and such solvent is added to the organic materials.

5. The method of claim 1 wherein the organic materials are added to the solvent.

6. The method of claim 4 wherein the solvent further includes dichloromethane.

7. The method of claim 1 wherein element (c) includes heating the solution at a temperature in a range between 50 and 100° Centigrade to evaporate the solvent.

8. The method of claim 1 wherein the suspension is mixed by a magnetic stirrer, a turbine stirrer, or an ultrasonic horn.

9. The method of claim 1 further including providing a controlled atmosphere for evaporation, wherein the controlled atmosphere is at a pressure in a range of 10⁻¹ to 10⁻³ Torr causing the solvent to evaporate and form the homogeneous mixture of organic powder.

10. The method of claim 7 wherein the controlled atmosphere includes an inert gas such as nitrogen gas, argon gas or a mixture thereof.

11. The method of claim 2 wherein the homogeneous mixture of organic powder is compacted at pressures in a range of 3,000 to 20,000 pounds per square inch to form the pellet.

12. The method of claim 8 wherein the suspension is mixed by the ultrasonic horn at a frequency in a range of 10-30 kHz.
